(19) United States
(12) Patent Application Publication
(10) Pub. No.: US 2009/0045418 A1
(43) Pub. Date: Feb. 19, 2009

(54) Light emitting diode (LED) with longitudinal package structure

(76) Inventor: Hsin Hui Yeh, Hsinchu City (TW)

Correspondence Address: REED SMITH LLP;Suite 1400, 3110 Fairview Park Drive, Falls Church, VA, 22042, US

(21) Appl. No.: 12/003,371

(22) Filed: Dec. 21, 2007

(30) Foreign Application Priority Data
Aug. 17, 2007 (TW) 096130412

(51) Int. Cl. H01L 33/00

(52) U.S. Cl. 257/91; 257/98; 257/E33.058

(57) ABSTRACT

The present invention provides erected LED package structure, which includes: a carrier substrate having a first surface, a second surface and a plurality of through holes passed through the first surface and the second surface of the carrier substrate, and the conductive material filled with each of the through holes; a LED having a semiconductor layer capable of the light emitting and an N electrode and a P electrode formed on the two sides of the semiconductor layer thereon; a first transparent carrier substrate having a metal layer thereon, in which the metal layer electrically connected to the N electrode of the LED and to the conductive material which is formed on the first surface of the carrier substrate; a second transparent carrier substrate having another metal layer thereon, in which another metal layer electrically connected to the P electrode of the LED and to another conductive material which is formed on the first surface of the carrier substrate; and a plurality of connecting elements electrically connected to the plurality of conductive material which is formed on the second surface of the carrier substrate.

### BACKGROUND OF THE INVENTION

1. Field of the Invention

The present invention is a light emitting diode (LED) package structure and more particularly is a package structure that the LED is vertically disposed to form a LED with longitudinal package structure.

2. Description of the Prior Art

Light emitting diode (LED) is a light emitting element is an illuminate element used to directly transform the electrical power to light power without transforming the electrical power to heat power. Therefore, LED is also called the luminescence emitting element. LED not only includes high illuminant efficiency but also is a micro solid state illuminator made in a semiconductor chip form. The voltage is inputted in two sides of the p-n junction and the current is able to flow through to generate electrons and holes flowing toward the p-n junction, and the electrons and holes are connected with the p-n junction to release photons.

Generally, the illumination of the LED in the present art is equal to or half of the efficiency of the illumination of the cold cathode fluorescent lamp (CCFL). The illuminant efficiency of the LED is related to the illuminant efficiency of the semiconductor chip itself and the extraction efficiency of the semiconductor chip package structure. The development of the illuminant efficiency is to develop the electroluminescent material and to increase the crystallizability of the semiconductor chip to enhance the quantum efficiency inside the semiconductor chip.

By the extraction efficiency of the LED package structure, the light generated by the semiconductor chip is reflected to the interior of the semiconductor chip by the interface total reflection. Because the light was reflected to the interior of the semiconductor by the interface total reflection, the reflective light was absorbed by the illuminant layer, electrode and substrate. Therefore, the extraction efficiency from the exterior to the semiconductor is less than the photon efficiency in the interior of the semiconductor.

According to the description above, the LED is a light source with lower power consumption than the conventional incandescent lamp or fluorescent lamp and the size of LED is smaller and lighter than the conventional lamps. But how to enhance the extraction efficiency of the LED package structure to get higher overall efficiency in the quantum efficiency inside the semiconductor chip of the LED is the important issue in current technology.

### SUMMARY OF THE INVENTION

According to the problems described above, the main object of the present invention is to provide a light emitting diode (LED) with longitudinal package structure used to decrease the covered portion of the LED and enhance the illuminative efficiency.

Another object of the present invention is to produce the transparent carrier substrate and LED at the same time and reduce the package time of the LED.

Another object of the present invention is to saw the LED package structure by customers' request after the LED is electrically connected to the carrier substrate without increasing the package time.

The other object of the present invention is to a backlight module made by a plurality of LEDs used to be the vertical backlight source of the liquid crystal panel (LED) display.

According the objects describe above, the present invention discloses a light emitting diode (LED) with longitudinal package structure comprising a carrier substrate, a LED, a first transparent substrate, a second transparent substrate, a plurality of connecting elements and a light focusing mask. The carrier substrate includes a first surface and a second surface, and a plurality of through holes pass through the first surface and the second surface and each of the though holes is filled with the conductive material. The LED includes an N electrode and a P electrode disposed at two sides of a semiconductor layer. The first transparent substrate includes a first metal layer disposed thereon, and the metal layer is electrically connected to the N electrode of the LED and the conductive material of the first surface of the carrier substrate. The second transparent substrate includes a second metal layer disposed thereon, and the second metal layer is electrically connected to the P electrode of the LED and the other conductive material of the first surface of the carrier substrate. The connecting elements are electrically connected to the conductive materials of the second surface of the carrier substrate. The light focusing mask is used to cover the first surface, the LED, the first transparent substrate and the second transparent substrate.

### BRIEF DESCRIPTION OF THE DRAWINGS

FIG. 1 is a sectional view showing a light emitting diode (LED) structure.

FIG. 2 is a view showing a carrier substrate used in the present invention

FIG. 3A is a top view showing the transparent carrier substrate used in the LED package structure in the present invention.

FIG. 3B is a sectional view of FIG. 3A.

FIGS. 4A-4B are views showing a stacked LED with sandwich structure.

FIG. 5A is a top view showing the carrier substrate shown in the present invention.

FIG. 5B is a sectional view showing the carrier substrate shown in the present invention.

FIG. 6A is a sectional view showing the LED with sandwich structure is going to electrically connect to the carrier substrate.

FIG. 6B is a sectional view showing the LED with sandwich structure is electrically connected to the carrier substrate.

FIG. 7 is a sectional view showing a LED with sandwich structure and a light focusing mask.

FIG. 8 is a sectional view showing a plurality of LEDs with sandwich structure and a light focusing mask.

### DESCRIPTION OF THE PREFERRED EMBODIMENT

The following detailed description of the present invention describes a light emitting diode package structure necessary to provide an understanding of the present invention, but does not cover a complete structure composition and the operating theory. The portions relating to the conventional techniques are briefly described, and the parts of the drawings are not proportionally drafted. While embodiments are discussed, it is not intended to limit the scope of the present invention. Except expressly restricting the amount of the components, it is appreciated that the quantity of the disclosed components may be greater than that disclosed.

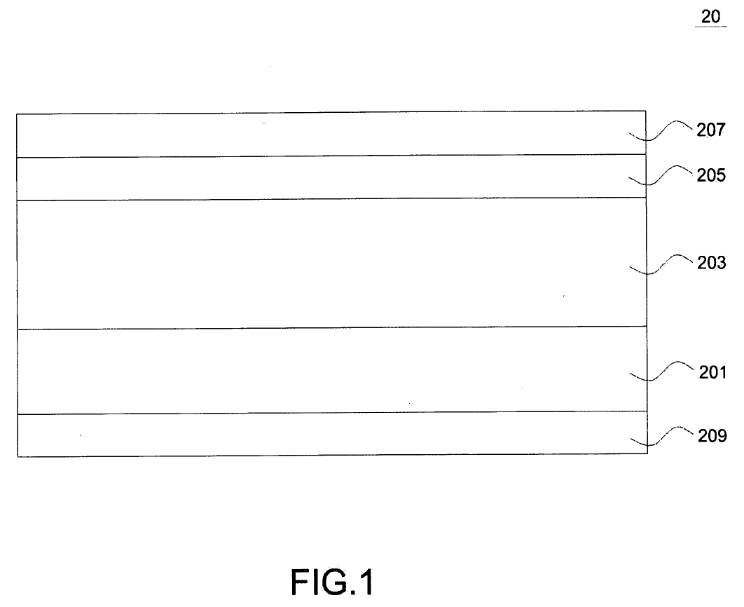

Please referring to FIG. 1, it is a sectional view showing a light emitting diode (LED) structure. The LED structure 20 includes a substrate 201, an epitaxy stacked layer 203, a transparent conductive layer 205, an electrode 207. The epitaxy stacked layer 203 is formed on the substrate 201. The transparent conductive layer 205 is formed on the epitaxy stacked layer 203. The electrode 207 is formed on the transparent conductive layer 205 and the electrode 209 is disposed below the substrate 201. It should be noted that the LED package structure in the present invention can be used in red light LED, green light LED, blue light LED, white light LED and so on. The LED using the package structure shown in FIG. 1 should be included in the present invention. Besides, in order to increase the extraction efficiency of the LED, there are some openings disposed on the electrode 207 and the electrode 209. Therefore, the light generated by LED 20 can be emitted to increase the strength of the illumination.

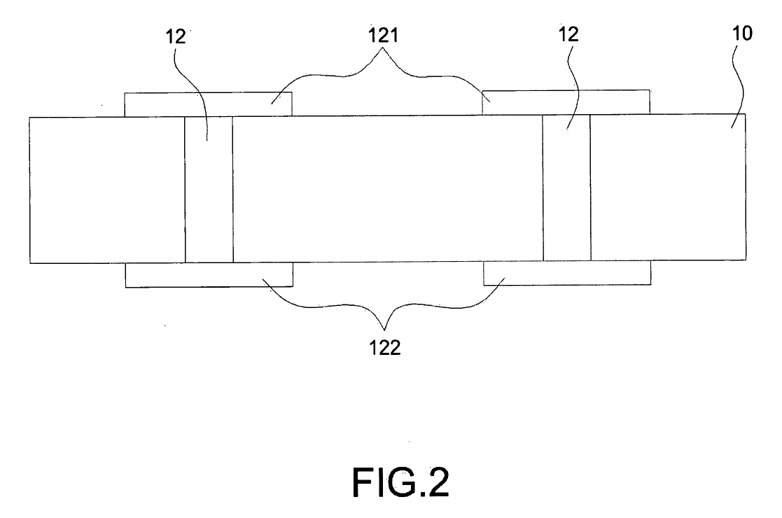

Now referring to FIG. 2, it is a carrier substrate 10 used in the present invention. As shown in FIG. 2, the carrier substrate 10 includes a first surface, a second surface and a plurality of thought holes 12 cutting across the first surface and the second surface. The through holes are formed by the method of micro drilling. Then, there is an electroplate layer 121/122 formed near each of the through hole 12. After the package process described above, the carrier substrate 10 is in the solder pot, then each of the through holes is filled with solder. It should be noted that the electroplate layer 121/122 in the present invention is formed as an extensional portion in two sides of the through hole on the top surface and the bottom surface of the carrier substrate 10. The extensional electroplate layer 121 on the top surface of the carrier substrate 10 is used to be the reflective layer of the LED. The extensional electroplate layer 122 on the bottom surface of the carrier substrate 10 is used to be the connecting point of the LED and the connecting interface for thermal fin. The carrier substrate 10 is packaged as the common circuit, so the detailed package process is omitted.

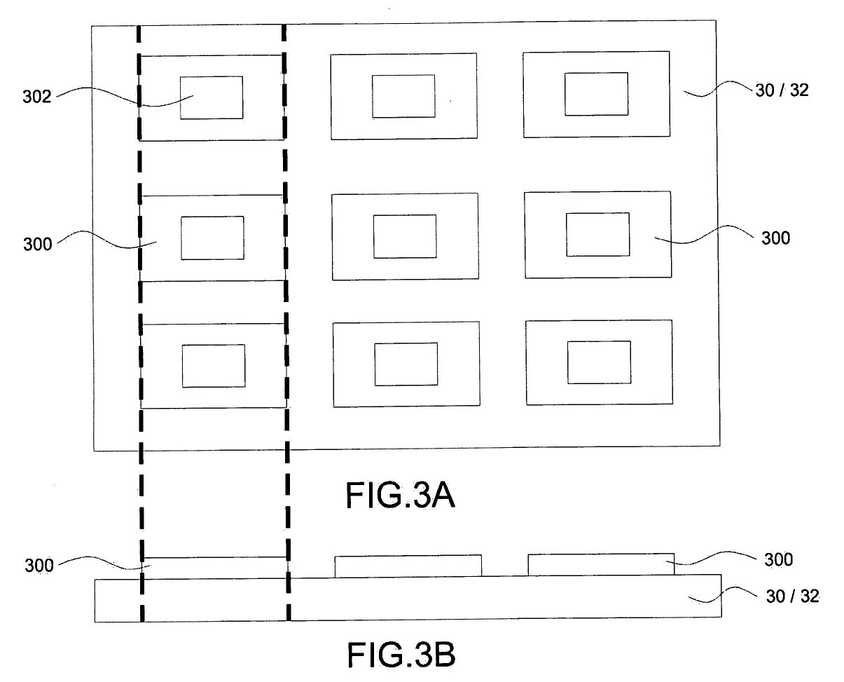

Now please referring to FIG. 3A and FIG. 3B, those are the top view and the sectional view of the transparent carrier substrate used in the LED package structure in the present invention. As shown in FIG. 3A, a plurality of standalone metal layers with equal size are disposed on the transparent substrate 30/32. The method of forming the metal layer is: forming a metal layer on the transparent carrier substrate 30/32; coating a photoresist layer on the metal layer and exposed by a patterning mask; removing a portion of the metal layer by eroding method; after removing a portion of the photoresist layer, a plurality of standalone metal layers with equal size are formed on the transparent carrier substrate 30/32. In addition, the size of the metal layer is little bigger than the LED 20.

Besides, the step of forming the metal layers 300 on the transparent carrier substrate 30/32 includes: coating the photoresist layer on the transparent carrier substrate 30/32; forming a concave or channel on the photoresist layer after exposing and developing by a patterning mask; filling the metal material in the concave or channel and removing the photoresist layer to form the metal layer 300 on the transparent carrier substrate 30/32. It should be noted that each of the metal layer 300 alternatively includes an opening, which is corresponding to the opening on the electrode 207/209 of the LED 20. The metal material 300 in the present invention is formed by evaporating process or sputtering process. But in the preferred embodiment, the metal material is formed by plating.

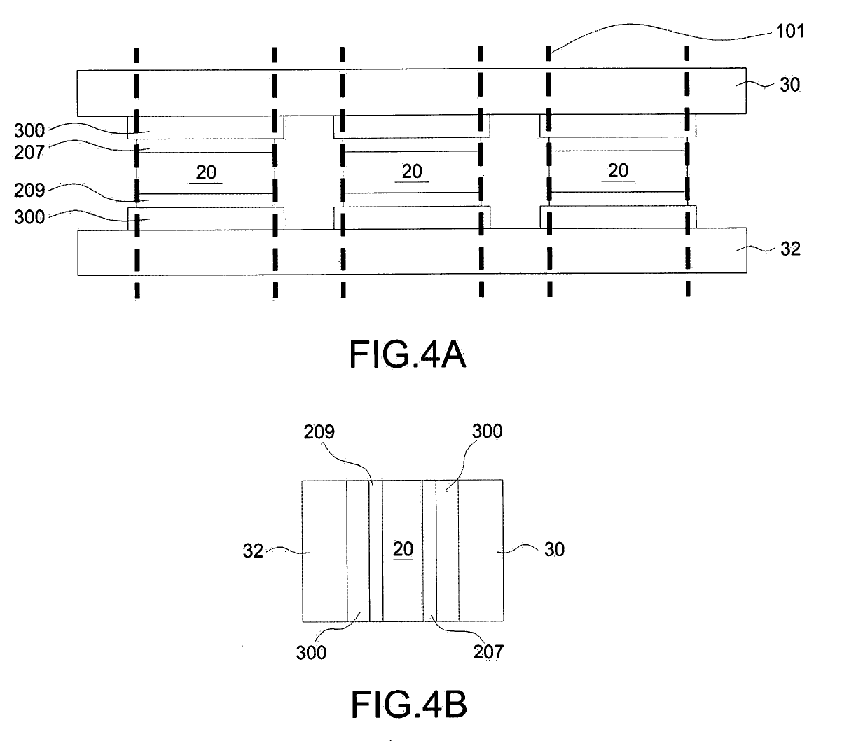

Please referring in FIG. 4A, it is a stacked LED with sandwich structure. First of all, the packaged LED 20 was cut into an individual chip. The LED 20 is moved by a transferred device and the electrode 209 in each of the LED 20 is stuck on the metal layer 300 of the transparent carrier substrate 32 by conductive glue (not shown). Therefore, the electrode 209 of the LED 20 is electrically connected to the metal layer 300 of the transparent carrier substrate 32. In the present embodiment, the conductive glue is a solder paste. After the process described above, after a suitable alignment step, the transparent carrier substrate 30 is stuck on the other electrode 207 in each of the LED 20. Similarity, the electrode 207 of the LED 20 is electrically connected to the metal layer 300 of the transparent carrier substrate 30, as shown in FIG. 4A.

Because the size of the metal layer 300 on the transparent carrier substrate 30/32 is bigger than the electrode 207/209 of the LED 20, a portion of the metal layer 300 on the transparent carrier substrate will be cut when the LED 20 is cut by following the sawing line 101 shown in FIG. 4A. After the sawing step for the transparent carrier substrate 30/32 was done, a few of LEDs with sandwich structure were formed. And the exposed metal layers 300 are disposed on the two sides of each of the LED 20 with sandwich structure, as shown in FIG. 4B.

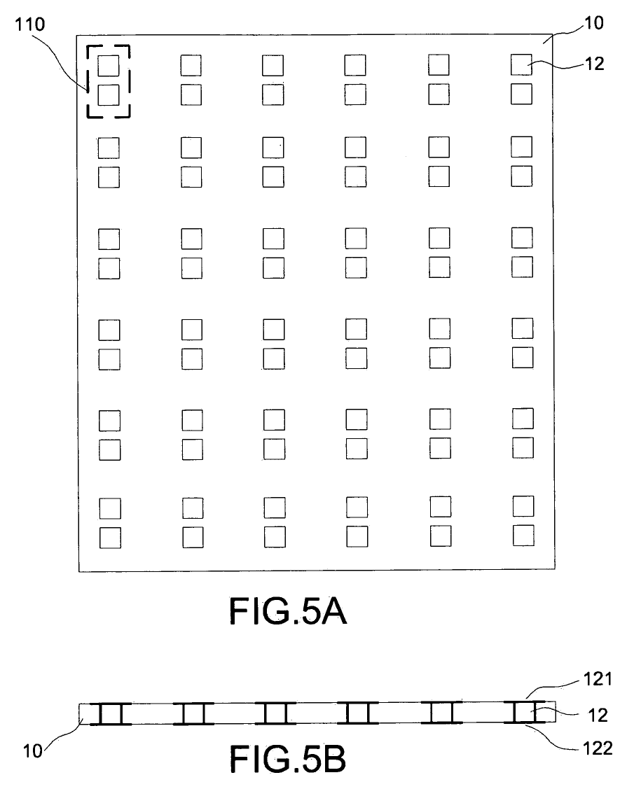

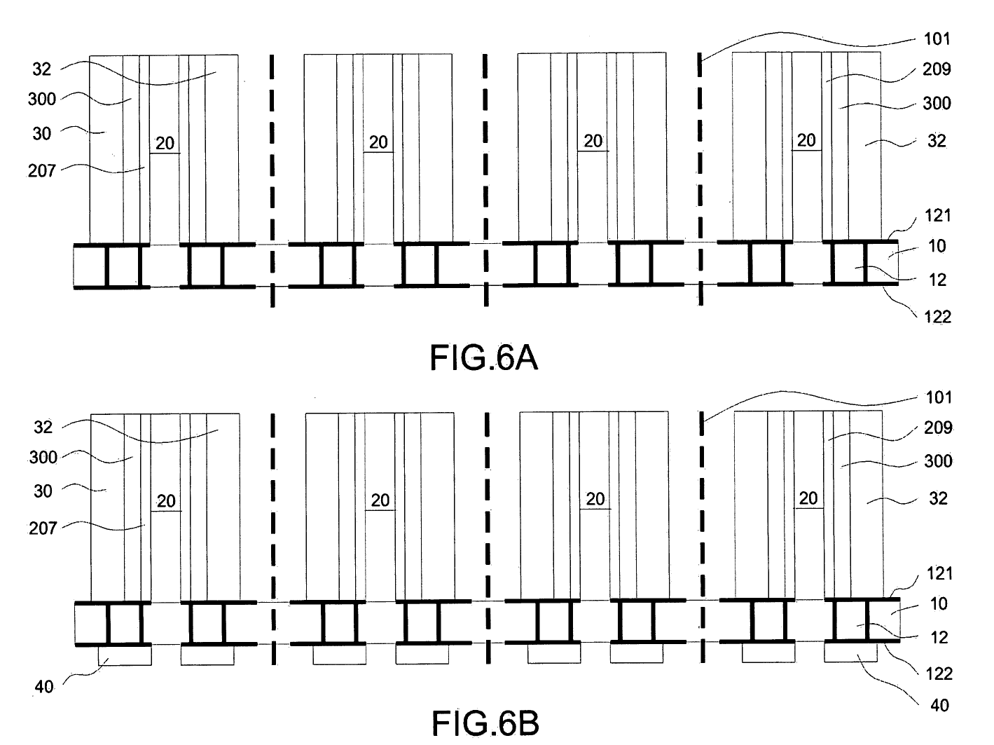

Now referring to FIG. 5A and FIG. 5B, those are the top view and the sectional view of the carrier substrate shown in FIG. 2. As shown in FIG. 5A, the carrier substrate 10 includes a first surface, a second surface and a plurality of thought holes 12 cutting across the first surface and the second surface. The through holes are filled with conductive material, such as solder, which is used to be a connecting point. Each of the through hole 12 is disposed on the edge of the first surface and the second surface and includes an extensional electroplate layer 121/122. The exposed end of the metal layer 300 of the LED 200 with sandwich structure is electrically connected to the connecting pairs 110 of the carrier substrate 10. As shown in FIG. 6A, obviously, each of the LED 20 with sandwich structure is vertically raised to electrically connect to the connecting point. A plurality of connecting elements 40, such as solder bump or metal lead, are formed on the connecting points of the second surface of the carrier substrate 10, as shown in FIG. 6B.

When the connecting element 40 is electrically connected to a power source, the LED 20 will generate light. The light generated by LED 20 can pass through the two sides of the transparent carrier substrate 30/32 to illuminate. Because the LED 20 with sandwich structure in the present invention is vertically packaged, the illumination of the LED 20 is covered by the electrode is reduced and the extraction efficiency of the LED 20 is enhanced.

Before the sawing step, the package process in the present invention can cut the LED 20 with sandwich structure into individual packaged element in accordance with customers' request or a few of LEDs with sandwich structure and equal size. The connecting points in the carrier substrate 10 are connected to let the LEDs with sandwich structure illuminate evenly. Because the connecting method described above is well known, it is not necessary to describe more detail. Besides, it should be noted that the main part of the LED 20 is packaged as a sandwich structure in accordance with the transparent carrier substrate 30/32 in the embodiment of the present invention. Therefore, when the LED 20 with sandwich structure is cut, it is not necessary to use some resins to protect to have illumination function.

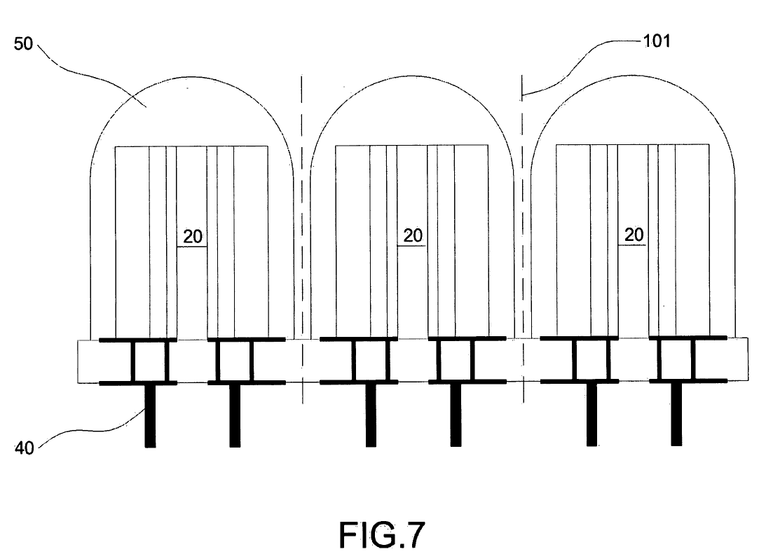

However, in order to let the LED 20 with sandwich structure generate high illuminative light, there is a light focusing mask 50 is added near the LED 20 in the present invention. There is a reflective layer (not shown) disposed on the internal side of the light focusing mask 50 and forms a better light reflective path in accordance with the extensional electroplate layer 121 on the first surface of the carrier substrate 10 to increase the illuminative efficiency. It should be noted that the method to add the light focusing mask 50 in the present invention is like the normal package method of the conventional LED. After each of the Led is cut into an individual chip, the light focusing mask is added one after another. The method to add the light focusing mask is by sticking way or molding by a fasten element, it is not limited in the present invention. The material of the light focusing mask in the present invention is plastic material but is not limited. After the structure shown in FIG. 6B was done, the light focusing mask 50 is stuck or molded to cover each of the LED 20 with sandwich structure, as shown in FIG. 7. Obviously, the method described above is able to avoid the LED 20 with sandwich structure being polluted. Because the reflective layer (not shown) is disposed on the internal side of the light focusing mask 50 to have a better light reflective path in accordance with the extensional electroplate layer 121 of the first surface of the carrier substrate 10 to increase the illuminant efficiency.

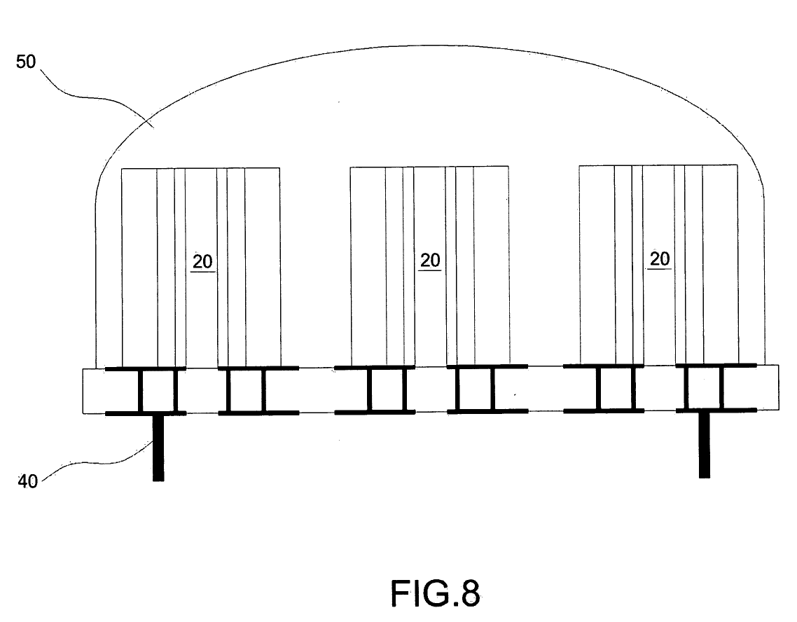

When the light focusing mask 50 is stuck or molded to cover the LED 20 with sandwich structure, the single LED 20 with sandwich structure is shown in FIG. 7. And there is a plurality of LEDs 20 with sandwich structure shown in FIG. 8. The final step is to cut the LED package structure by following the sawing line 101, the package structure of the present invention is done. It should be noted that the light focusing mask 50 can be formed a semi-sphere shape, as shown in FIG. 7 and FIG. 8. However, in different embodiment, the light focusing mask 50 can be formed a different geographic shape. Especially, when the LED 20 with sandwich structure is used to be a illuminative source or backlight source, the light focusing mask 50 is formed a plate structure.

Obviously, when the package structure of the present invention shown in FIG. 8 is used to connect with a power source device, it is formed a vertical backlight module. Therefore, when the backlight module of the present invention is connected to a liquid crystal panel (LCD) (not shown), the package structure is used in a LCD display. At the time, the light focusing mask 50 with plate structure is used to reduce the thick of the backlight module. In addition, when the LEDs 20 with sandwich structure shown in FIG. 8 is consist of at least one red light LED, at least one green light LED and at least one blue light LED, it is formed an light source.

Although specific embodiments have been illustrated and described, it will be appreciated by those skilled in the art that various modifications may be made without departing from the scope of the present invention, which is intended to be limited solely by the appended claims.

What is claimed is:

1. A light emitting diode (LED) package structure comprising:
a carrier substrate including a first surface and a second surface, and a plurality of through holes passing through the first surface and the second surface and each of the though holes is filled with the conductive material;
a LED including a N electrode and a P electrode disposed at two sides of a semiconductor layer;
a first transparent substrate including a first metal layer disposed thereon, and the metal layer is electrically connected to the N electrode of the LED and the conductive material of the first surface of the carrier substrate;
a second transparent substrate including a second metal layer disposed thereon, and the second metal layer is electrically connected to the P electrode of the LED and the other conductive material of the first surface of the carrier substrate;
a plurality of connecting elements electrically connected to the conductive materials of the second surface of the carrier substrate; and
a light focusing mask used to cover the first surface, the LED, the first transparent substrate and the second transparent substrate.

2. The package structure of claim 1, wherein the first transparent substrate and the second transparent substrate are electrically connected to the N electrode and P electrode the LED by conductive glue.

3. The package structure of claim 1, wherein the connecting elements are selected from the group consisted of: metal lead, metal bump and solder ball.

4. The package structure of claim 1, wherein the first metal layer of the transparent substrate includes an opening.

5. The package structure of claim 1, wherein the second metal layer of the transparent substrate includes an opening.

6. The package structure of claim 1, wherein the light focusing mask is made by plastic.

7. The package structure of claim 1, wherein the conductive material is extended around the through hole of the first surface of the carrier substrate.

8. The package structure of claim 1, wherein the conductive material is extended around the through hole of the second surface of the carrier substrate.

9. The package structure of claim 1, wherein the conductive material is extended around the through hole of the first surface and the second surface of the carrier substrate.

10. An illuminant device package structure comprising:
a carrier substrate including a first surface and a second surface, and a plurality pairs of through hole pass through the first surface and the second surface and each of the though holes is filled with the conductive material;
a plurality of LEDs electrically connected to a plurality pairs of the conductive materials on the carrier substrate;
a plurality of connecting elements electrically connected to the conductive materials on the second surface of the carrier substrate; and
a light focusing mask used to cover the first surface, the LED, the first transparent substrate and the second transparent substrate;
wherein each of the LED structure comprising:
a N electrode and a P electrode disposed at two sides of a semiconductor layer;
a first transparent substrate including a first metal layer disposed thereon, and the metal layer is electrically connected to the N electrode of the LED and the conductive material of the first surface of the carrier substrate; and
a second transparent substrate including a second metal layer disposed thereon, and the second metal layer is electrically connected to the P electrode of the LED and the other conductive material of the first surface of the carrier substrate.

11. The package structure of claim 10, wherein the first transparent substrate and the second transparent substrate are made by glass.

12. The package structure of claim 10, wherein the first transparent substrate and the second transparent substrate are electrically connected to the N electrode and P electrode the LED by conductive glue.

13. The package structure of claim 10, wherein the connecting elements are selected from the group consisted of: metal lead, metal bump and solder ball.

14. The package structure of claim 10, wherein the conductive material is extended around the through hole of the first surface of the carrier substrate.

15. The package structure of claim 10, wherein the conductive material is extended around the through hole of the second surface of the carrier substrate.

16. The package structure of claim 10, wherein the conductive material is extended around the through hole of the first surface and the second surface of the carrier substrate.

17. The package structure of claim 10, wherein the first metal layer of the transparent substrate includes an opening.

18. The package structure of claim 10, wherein the second metal layer of the transparent substrate includes an opening.

19. The package structure of claim 10, wherein the LEDs are selected from the group consisted of: red light LEDs, green light LEDs and blue light LEDs.

20. A backlight module including a flat panel light source device and a power source device, characterized by:
the flat panel light source device comprising:
a carrier substrate including a first surface and a second surface, and a plurality pairs of through hole pass through the first surface and the second surface and each of the though holes is filled with the conductive material;
a plurality of LEDs electrically connected to a plurality pairs of the conductive materials on the carrier substrate;
a plurality of connecting elements electrically connected to the conductive materials on the second surface of the carrier substrate; and
a light focusing mask used to cover the first surface, the LED, the first transparent substrate and the second transparent substrate;
wherein each of the LED comprising:
a N electrode and a P electrode disposed at two sides of a semiconductor layer;
a first transparent substrate including a first metal layer disposed thereon, and the metal layer is electrically connected to the N electrode of the LED and the conductive material of the first surface of the carrier substrate; and
a second transparent substrate including a second metal layer disposed thereon, and the second metal layer is electrically connected to the P electrode of the LED and the other conductive material of the first surface of the carrier substrate.
